(19) United States
(12) Patent Application Publication
(10) Pub. No.: US 2008/0203547 A1
(43) Pub. Date: Aug. 28, 2008

(54) INSERT MOLDED LEADFRAME ASSEMBLY

(76) Inventor: Steven E. Minich, York, PA (US)

Correspondence Address: WOODCOCK WASHBURN, LLP, CIRA CENTRE, 12TH FLOOR, 2929 ARCH STREET, PHILADELPHIA, PA, 19104-2891, US

(21) Appl. No.: 11/678,775

(22) Filed: Feb. 26, 2007

(51) Int. Cl. H01L 23/12

(52) U.S. Cl. 257/669; 439/74

(57) ABSTRACT

An insert molded leadframe assembly (IMLA) for an electrical connector is disclosed. The IMLA may include an array of electrically conductive contacts, a dielectric leadframe housing overmolded onto the array of contacts, and a mass disposed within the leadframe housing. The additional mass may shift the IMLA's center of gravity, thereby providing a counterbalance to a non-proportional ball-grid array connector.

### FIELD OF THE INVENTION

The invention relates generally to electrical connectors. More specifically, the invention relates to an insert molded lead frame assembly.

### BACKGROUND OF THE INVENTION

Electrical connectors, such as ball-grid array (BGA) connectors, are usually mounted on the surface of a substrate using multiple solder connections. The solder connections act as electrical and mechanical connections between the substrate and contact pads on the connector.

The weight of some BGA connectors is not distributed evenly across the solder balls (or other fusible elements). For example, the center of gravity of some BGA connectors, such as right angle BGA connectors, may be offset from the geometric center thereof to an extent that causes the connector to tilt (or tip) on the substrate. Such tilting can vary the pressures on the solder balls of the ball-grid array. In other words, the weight of the connector may be distributed unevenly among the solder balls. Such uneven distribution can result in differences in the collapsing properties and the height of the solder balls as the solder balls are melted to form electrical connections. These factors degrade the strength and integrity of the resulting solder connections. In extreme cases, tilting can result in separation of the solder ball from the associated contact pad, thereby inhibiting the formation of an electrical connection.

### SUMMARY OF THE INVENTION

The invention provides an insert molded leadframe assembly (IMLA) that may contain a mass to evenly distribute the weight of the IMLA over the solder balls.

Such an IMLA may include an array of electrically conductive contacts, a dielectric leadframe housing overmolded onto the array of contacts, and a mass disposed within the leadframe housing. Initially, the IMLA may have a first center of gravity in the absence of the mass. When the mass is added, the IMLA may have a second center of gravity about which the IMLA is balanced. In such a balanced IMLA, there may be an even distribution of weight and the solder balls may be compressed uniformly.

### BRIEF DESCRIPTION OF THE DRAWINGS

FIG. 1 is a side view of an insert molded leadframe assembly (IMLA).

FIG. 2 is a side view of a conductive leadframe after stamping.

FIG. 3 is a side view of the conductive leadframe of FIG. 2 after overmolding.

FIG. 4 is a side view of the conductive leadframe of FIG. 2 with the carrier strip removed, depicting the center of gravity of the entire connector assembly.

FIG. 5 is a perspective view of an IMLA being positioned into a connector housing.

FIG. 6 is a perspective view of the IMLA of FIG. 5 almost completely inserted into the connector housing.

FIG. 7 is a perspective view of the IMLA of FIG. 5 completely inserted into the connector housing

FIGS. 8A and 8B are perspective views of a right angle connector.

### DETAILED DESCRIPTION OF ILLUSTRATIVE EMBODIMENTS

The figures depict an embodiment of an insert molded leadframe assembly (IMLA) for use in a right-angle ball-grid array (BGA) connector. The IMLA is described in conjunction with this particular type of connector for exemplary purposes only; alternative embodiments of the IMLA can be configured for use with virtually any type of surface-mounted connector.

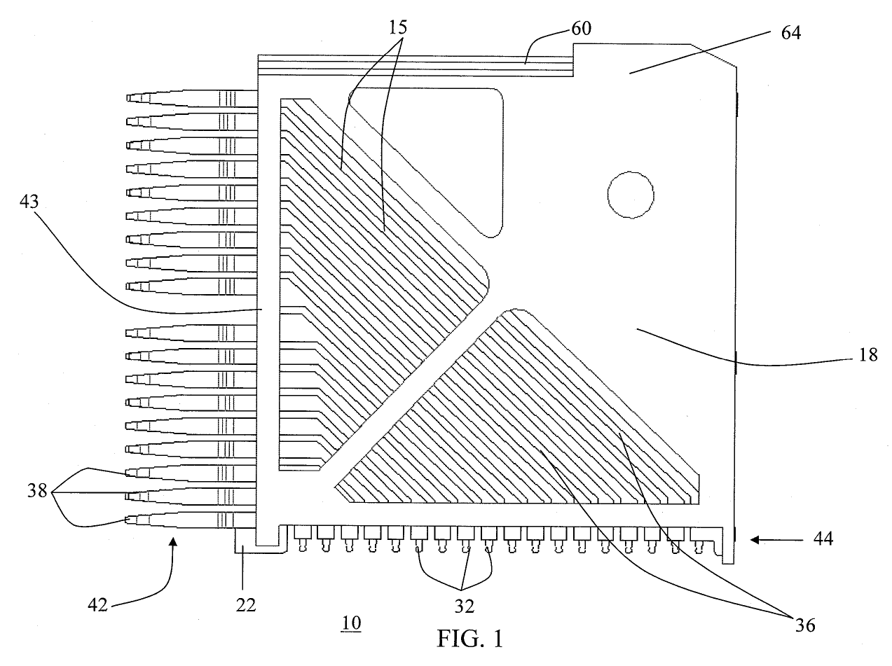

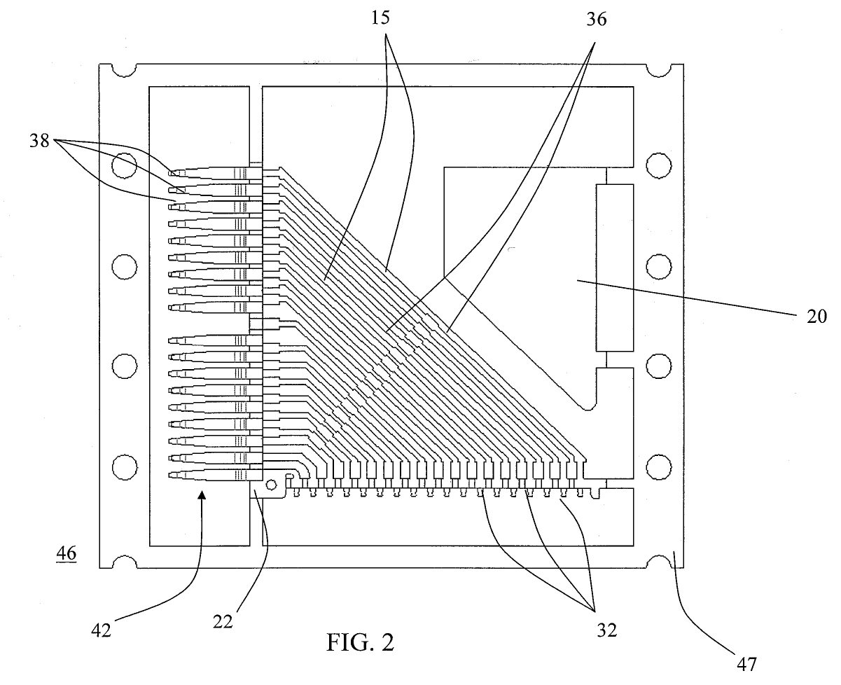

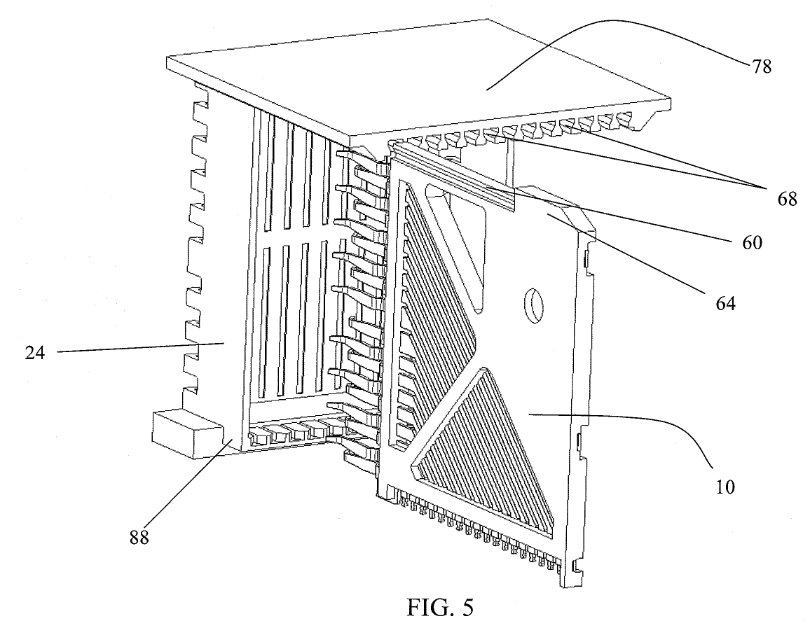

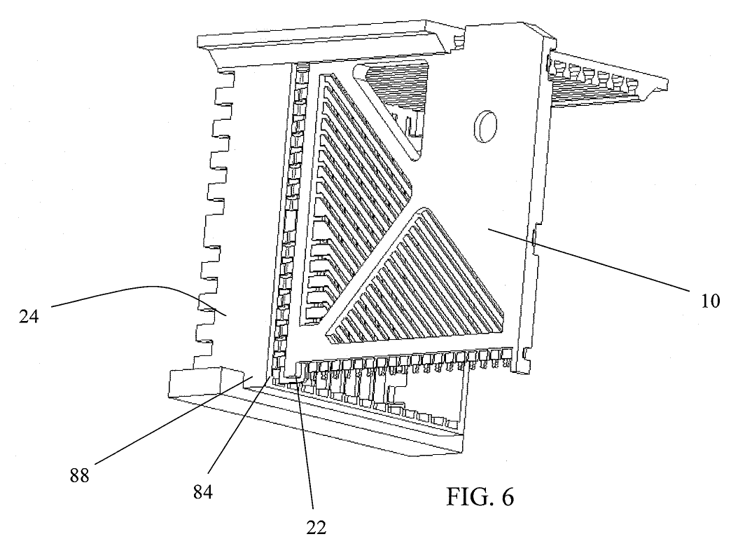

FIG. 1 depicts an example embodiment of an IMLA 10. As shown, the IMLA 10 may include a plurality of electrically conductive contacts 15 that extend through a leadframe housing 18. The IMLA 10 may also include a mass 20 (FIG. 2) embedded within the leadframe housing 18, and an alignment member 22 for positioning the IMLA 10 in a connector housing 24 (shown in FIGS. 5-6). A void in the plastic, shown as an exemplary right angle triangle in FIGS. 1 and 5-8B, may also be used to shift the center of gravity of the electrical connector. The void may take any shape or size.

Each contact 15 may include a terminal end 32, a lead portion 36, and a mating end 38. Each lead portion 36 may extend between its respective terminal end 32 and its respective mating end 38. The lead portions 36 may bend such that the terminal ends 32 extend in a direction orthogonal to the direction in which the mating ends 38 extend. The direction in which the terminal ends 32 extend relative to the mating ends 38 may vary, depending on the use of the connector.

The contacts 15 may be arranged side-by-side within the leadframe housing 18 so that the mating ends 38 form a linear contact array 42 adjacent to a front edge 43 of the housing 18, and the terminal ends 32 form a horizontally-oriented row 44 along the bottom of the housing 18. As shown, the linear contact array 42 may be arranged as a contact column, though it should be understood that the linear contact array 42 could be arranged as a contact row. Also, though the IMLA 10 is depicted with a certain number of contacts 15, it should be understood that the IMLA 10 may include any desired number of contacts 15.

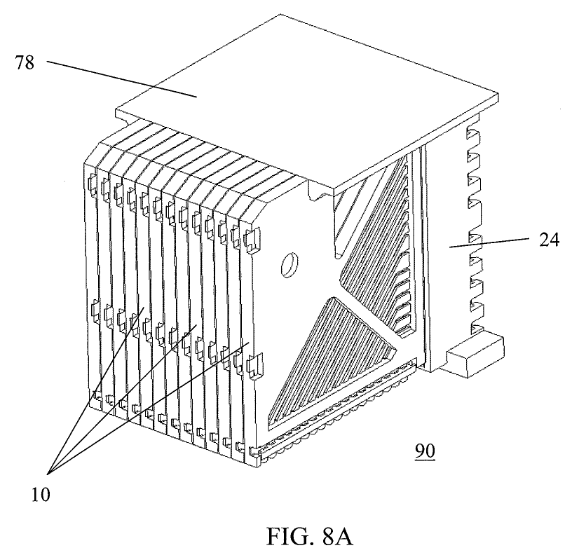

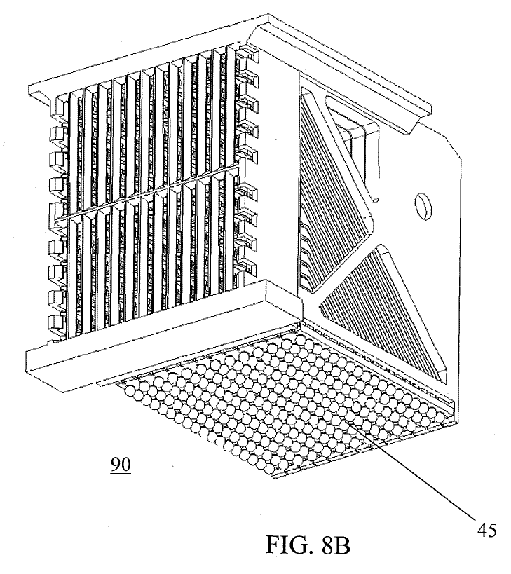

The terminal ends 32 of the contacts 15 may include fusible elements, such as solder balls for example. The solder balls may form a ball grid array 45 (Shown in FIG. 8B). The solder balls may each contact an associated contact pad on the printed circuit board (PCB) which may define the fusible area when the connector is mounted thereon.

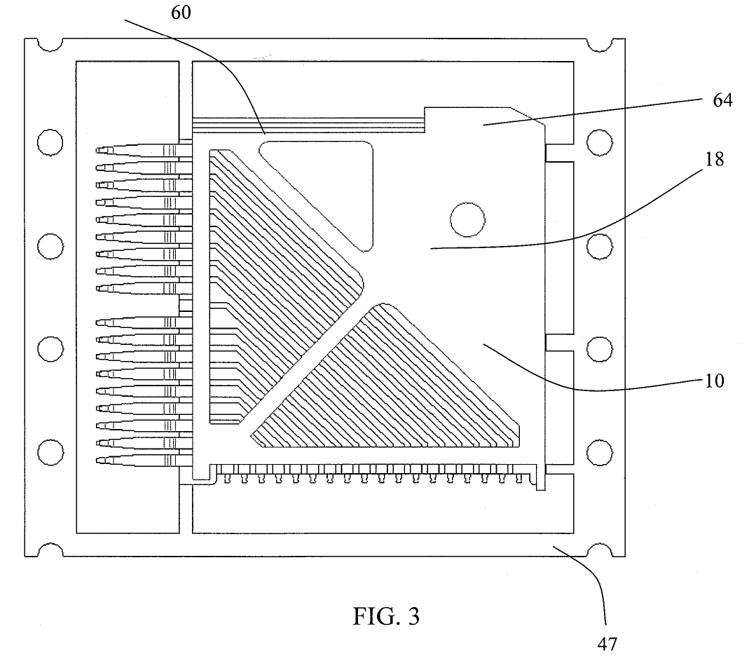

The IMLA 10 may be manufactured using well know techniques in the art. For example, the mass 20, the alignment member 22, and the contacts 15 may be stamped out of a conductive sheet 46. As shown in FIG. 2, the mass 20, the alignment member 22 and the contacts 15 remain attached to a carrier frame 47 after stamping. Next, the leadframe housing 18 may be overmolded onto the stamped out portions as depicted in FIG. 3. Accordingly, the leadframe housing 18 may be overmolded onto the contacts 15, the mass 20, and the alignment member 22. The leadframe housing 18 may be made of a dielectric material, such as a plastic, for example. The leadframe housing 18 may include an IMLA retention member 60 extending from a top portion 64 of the leadframe housing 18. The retention member 60 may be capable of engaging a retention slot 68 formed in the connector housing 24 (described below). The retention member 60 is depicted in the FIGs. as a dovetail, however, the member 60 is not limited to such a structure. For example, the member 60 and slot 68 combination may also be a tongue and groove fit.

The mass 20 is depicted as being positioned in an upper corner of the IMLA 10, and as having a certain shape. The mass 20, however, is not limited to the depicted position, nor is it limited to the depicted shape. Accordingly, mass 20 may have any position and any shape that may be capable of shifting the initial center of gravity of the IMLA 10.

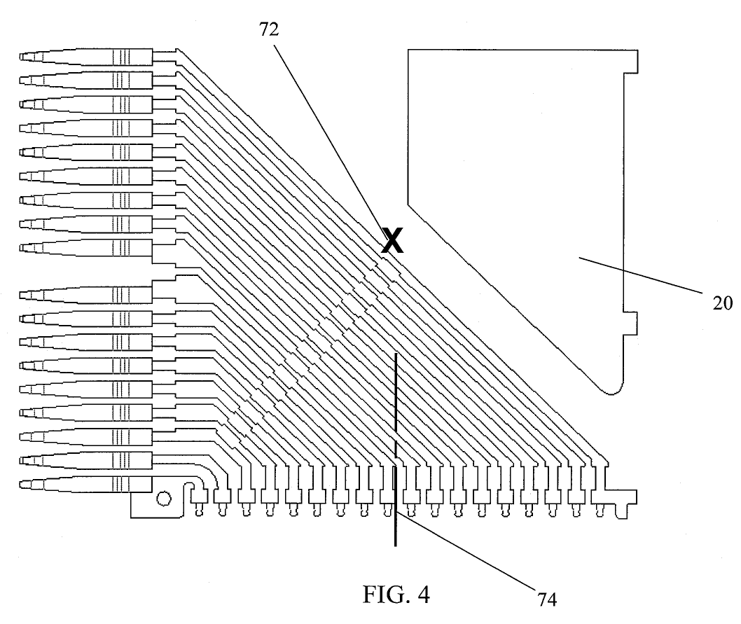

Typically, IMLA's do not contain the mass 20 and have an initial center of gravity that causes the connector, and particularly a right angle connector perched on the edge of a PCB to tilt away from a mounting surface of the PCB. With the addition of mass 20, the connector's initial center of gravity may be shifted to a second center of gravity 72. As shown in FIG. 4, the second center of gravity 72 may be substantially above a center 74 of the ball grid array 45. The mass 20 may weigh approximately 3 to 7 times as much as the plastic it replaces, with a 5.5 weight preferred. The weight of the mass, however, may depend on several factors, such as the number of contacts 15 and the size of the IMLA 10, for example. Preferably the mass 20 may have a weight that balances the IMLA 10 and shifts the IMLA's center of gravity to a position over the center of the ball grid array 45.

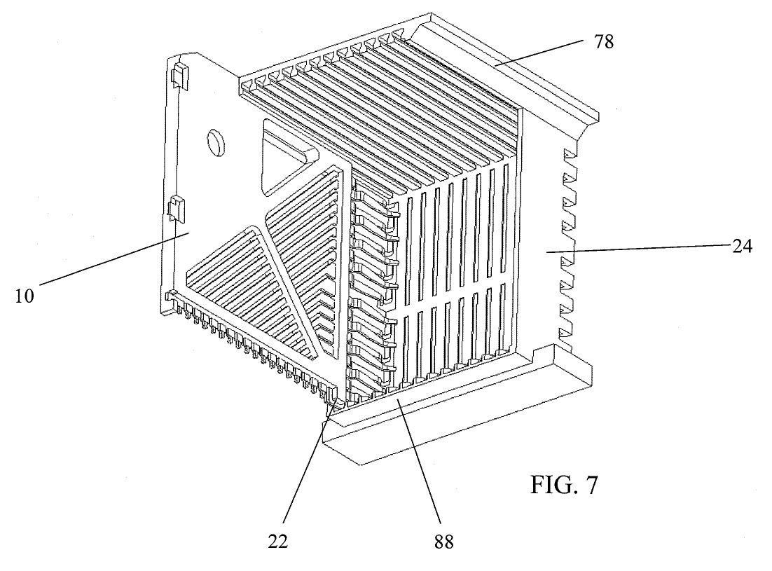

Once the IMLA 10 has been manufactured, it may be positioned into the connector housing 24. FIGS. 5-7 depict the IMLA 10 being positioned into the housing 24. As shown in FIG. 5, the retention member 60 may engage the retention slot 68 that is formed in a top portion 78 of the housing 24. When the IMLA 10 is almost fully inserted, as shown in FIG. 6, the alignment member 22 may engage an alignment slot 84 formed in a base 88 of the housing 24. The fit between the alignment member 22 and the slot 84 may have an interference fit or latch for retention to the housing 24. FIG. 7 shows the IMLA 10 fully inserted in the housing 24.

FIGS. 8A and 8B depict a completed right angle connector 90. As shown, the connector 90 may include a plurality of IMLAs 10. In that regard, the connector 90 may include any number of IMLAs 10. For example, as depicted, connector 90 may include thirteen IMLAs 10.

The connector 90 may be placed on a PCB so that the solder balls each substantially align with a corresponding contact pad on the PCB as noted above. The solder balls may subsequently be heated by a suitable process such as a reflow operation. The heating melts the solder balls, and upon cooling, forms electrical connections between the terminal ends 32 of the contacts 15 and the associated contact pads.

Typical right angle connectors have a center of gravity that is offset from the center of the ball grid array of the connector. The weight of the connectors (acting through the center of gravity), in combination with the reactive force exerted by the PCB on the connector by way of the solder balls, generate a moment on the connector. The moment, if not counteracted, can cause the connector to tilt, thereby causing at least some of the solder balls to lose contact with their corresponding contact pads or to not have a common geometry.

By using IMLAs 10, the connector 90 may have a center of gravity that may be substantially over the center of the connector's ball grid array 45. The combined additional mass 20 embedded within the leadframe housing 24 of each IMLA 10 may act as a counterweight that counteracts the moment acting on typical connectors. Accordingly, the above described tilting in the connectors may be prevented. In other words, the combined center of gravity of the connector housing 24 and the IMLAs 10 may be located over the ball grid array 45, more specifically over the center of the fusible area, so that the reactive force exerted by the solder balls in response to the weight of the connector 90 does not cause the connector 90 to tip. The addition of mass 20 in each IMLA 10 thereby can help to align and maintain contact between each solder ball and its associated contact pad when the connector 90 is placed on the PCB during installation.

1. A leadframe assembly comprising:
an array of electrically-conductive contacts;
a dielectric leadframe housing overmolded onto the array of contacts
a mass disposed within the leadframe housing such that the leadframe assembly has a first center of gravity in the absence of the mass and a second center of gravity with the mass, wherein the leadframe assembly is unbalanced about the first center of gravity and balanced about the second center of gravity.

2. The assembly of claim 1, wherein the mass is metal.

3. The assembly of claim 1, wherein the leadframe assembly is disposed on a carrier strip.

4. The assembly of claim 1, wherein the mass weighs substantially 3-7 times that of plastic.

5. An insert molded leadframe assembly (IMLA) having an initial center of gravity, the IMLA comprising:
an overmolded portion; and
a counterweight disposed in the overmolded portion, wherein the counterweight offsets the initial center of gravity to balance the IMLA.

6. The IMLA of claim 5 wherein the counterweight is metal.

7. The IMLA of claim 5, wherein the counterweight weighs substantially 5.5 times that of plastic.

8. The IMLA of claim 5, further comprising a carrier strip, wherein the IMLA is disposed on the carrier strip.

9. The IMLA of claim 5 further including a housing capable of receiving the IMLA.

10. An insert molded leadframe assembly (IMLA) for being positioned within a connector housing of a right-angle electrical connector, the IMLA comprising:
an array of electrically-conductive contacts;
a dielectric leadframe housing overmolded onto the array of contacts; and
a mass disposed on the leadframe housing such that the mass causes the right-angle connector to be balanced when the IMLA is positioned within the connector housing.

11. The IMLA of claim 10, wherein the mass is metal.

12. The IMLA of claim 10, wherein the mass weighs substantially 5.5 times that of plastic.

13. The IMLA of claim 10, further comprising a carrier strip, wherein the IMLA is disposed on the carrier strip.
